(19) United States
(12) Patent Application Publication
(10) Pub. No.: US 2015/0061653 A1
(43) Pub. Date: Mar. 5, 2015

(54) ANGLE DETECTION DEVICE

(71) Applicant: ALPS ELECTRIC CO., LTD., Tokyo (JP)

(72) Inventor: Tokuo NAKAMURA, Tokyo (JP)

(73) Assignee: ALPS ELECTRIC CO., LTD., Tokyo (JP)

(21) Appl. No.: 14/295,813

(22) Filed: Jun. 4, 2014

(30) Foreign Application Priority Data
Aug. 29, 2013 (JP) 2013-178567

(51) Int. Cl. G01B 7/30; G01R 33/09

(52) U.S. Cl. CPC G01B 7/30; G01R 33/09
USPC 324/207.21; 324/207.25

(57) ABSTRACT

Outputs from first and second magnetic detection units are applied to first to fourth output circuits, each being a differential amplifier, and therefore detection outputs S1 and S2 approximating a sine wave reversed in positive/negative polarity with each other and detection outputs S3 and S4 approximating a cosine wave reversed in positive/negative polarity with each other can be obtained. These detection outputs S1 to S4 are applied to a switching circuit, so that a partial detection output can be obtained at intervals of 90 degrees from the detection outputs S1 and S4. In a bias adding circuit, a bias voltage is applied to each partial detection output, so that the partial detection outputs become consecutive outputs to thereby obtain an angle detection output approximating a linear function.

### CLAIM OF PRIORITY

This application contains subject matter related to and claims the benefit of Japanese Patent Application No. 2013-178567 filed on Aug. 29, 2013, the entire contents of which is incorporated herein by reference.

### BACKGROUND OF THE DISCLOSURE

1. Field of the Disclosure

The present disclosure relates to an angle detection device in which a plurality of magnetic detection units detect a rotation magnetic field to obtain an analog output approximating a linear function which is proportional to a rotation angle.

2. Description of the Related Art

As an angle detection device that detects a rotation angle of a rotational body with a magnet, an angle detection device with a bridge circuit including a magnetoresistive effect element is used. Typically, two sets of bridge circuits are used to obtain a detection output approximating a sine wave from one bridge circuit, whereby a detection output approximating a cosine wave can be obtained from the other bridge circuit.

In order to detect the rotation angle of the rotational body, it is necessary to obtain a detection output of a linear function which is proportional to the rotation angle. In order to obtain the detection output of the linear function, an inverse tangent function (arctangent) is calculated from the detection output approximating the sine wave and the detection output approximating the cosine wave. In the related art, as a method of accurately calculating the inverse tangent function, a digital operation using an algorithm such as a codec is performed by A/D converting the detection output approximating the sine wave and the detection output approximating the cosine wave.

However, the digital operation using the algorithm has a disadvantage in that the operation is time-consuming. A highly accurate angle detection output can be obtained by the digital operation at a low rotation speed of the rotational body, but the operation cannot follow rotation of the rotational body when the rotational body rotates at a high rotation speed such as in a motor.

In Japanese Unexamined Patent Application Publication No. 2010-54495 and Japanese Translation Patent Publication No. 2011-508891, an angle detection device for obtaining a detection output close to a linear function without using a digital operation is disclosed.

In the angle detection device described in Japanese Unexamined Patent Application Publication No. 2010-54495, a magnetic sensor with a combination of a magnet and a magnetoresistive effect element is used. A rotational body is made of a ferromagnetic material, and a planar shape of the rotational body is a shape with a tangent function (tangent) added rather than a perfect circle. Using the rotational body, the detection output approximating the linear function can be obtained from the magnetic sensor.

However, it is very difficult to manufacture the rotational body with the tangent function added rather than the circle, and the manufacturing costs are increased.

In the angle detection device described in Japanese Translation Patent Publication No. 2011-508891, a rotating magnet and four sensor elements facing the rotating magnet are provided. Outputs approximating a sine wave and a cosine wave can be obtained from the sensor element, so that indirect division is performed by an analog multiplier from the two outputs. However, in the analog multiplier, an analog division circuit is required for a signal processing unit, and therefore the circuit configuration becomes complex.

These and other drawbacks exist.

### SUMMARY OF THE INVENTION

Embodiments of the present disclosure provide an angle detection device which can obtain an angle detection output approximating a linear function through a simple circuit configuration and follow a high-speed rotation.

According to an example embodiment, an angle detection device includes a first magnetic detection unit configured to be provided in a detection area to which a rotational magnetic field is applied so as to obtain a detection output approximating a sine wave being a function of a rotation angle of the rotational magnetic field; a second magnetic detection unit configured to be provided in the detection area to which the rotational magnetic field is applied so as to obtain a detection output approximating a cosine wave being a function of the rotation angle of the rotational magnetic field; a switching circuit configured to cut out a plurality of partial detection outputs approximating a linear function from analog detection outputs obtained from the first and second magnetic detection units; and a bias adding circuit configured to enable the plurality of partial detection outputs to be consecutive by applying a bias power to any one of the partial detection outputs so that the consecutive partial detection outputs are used as angle detection outputs.

In an angle detection device according to various embodiments, the analog detection outputs obtained from the magnetic detection units may be cut out to be consecutive by the switching circuit, and therefore the speed may be high and the circuit configuration may be simple in order to obtain the angle detection output. In addition, the analog outputs obtained from the magnetic detection units are used as is, or used by only passing through gain adjustment or the like, and therefore the angle detection output directly connected to the rotation angle of the rotational body can be obtained.

An angle detection device according to various embodiments may further include: an output circuit configured to obtain a first detection output from the first magnetic detection unit and a second detection output obtained by reversing positive/negative polarity with the first detection output, and a third detection output from the second magnetic detection unit and a fourth detection output obtained by reversing positive/negative polarity with the third detection output; and a comparator configured to compare either the first and second detection outputs or the third and fourth detection outputs. Here, switching timing of the switching circuit may be determined based on a comparison output from the comparator.

In an angle detection device according to various embodiments, each of the first, second, third, and fourth detection outputs may be cut out at intervals of 90 degrees by the switching circuit so that the partial detection outputs may be obtained.

Also, the first, second, third, and fourth detection outputs may be cut out in a range of ±45 degrees with a midpoint of the amplitude as a starting point. Accordingly, by obtaining the partial detection output in this range, the partial detection output approximating the linear function can be obtained.

In an angle detection device according to various embodiments, each of the first and second magnetic detection units may be constituted of a bridge circuit including a magnetoresistive effect element, and in a first magnetoresistive effect element included in the first magnetic detection unit and a second magnetoresistive effect element included in the second magnetic detection unit, directions of sensitivity axes may be orthogonal to each other.

In an angle detection device according to various embodiments, an analog output can be cut out from each of the first magnetic detection unit and the second magnetic detection unit in the switching circuit, and consecutive angle detection output obtained by applying bias can be obtained. Therefore, a circuit configuration is simple, and even when a rotation speed of the rotational body is high, the angle detection output which rapidly follows rotation can be obtained.

### BRIEF DESCRIPTION OF THE DRAWINGS

FIG. 1 is a plan diagram showing a rotational body and a magnetic detection unit in an angle detection device according to an embodiment of the present invention;

FIG. 2 is a circuit block diagram showing a circuit configuration of an angle detection device according to an embodiment of the present invention;

FIG. 3 is a line diagram showing four types of detection outputs from first and second magnetic detection units;

FIG. 4 is a line diagram showing a partial detection output obtained by cutting a detection output from first and second magnetic detection units;

FIG. 5 is a line diagram showing an angle detection output in which partial detection outputs are consecutive; and

FIG. 6 is a line diagram showing distribution of errors between the angle detection output shown in FIG. 5 and a linear function.

### DETAILED DESCRIPTION OF THE DISCLOSURE

The following description is intended to convey a thorough understanding of the embodiments described by providing a number of specific embodiments and details involving an angle detection device. It should be appreciated, however, that the present invention is not limited to these specific embodiments and details, which are exemplary only. It is further understood that one possessing ordinary skill in the art, in light of known systems and methods, would appreciate the use of the invention for its intended purposes and benefits in any number of alternative embodiments, depending on specific design and other needs.

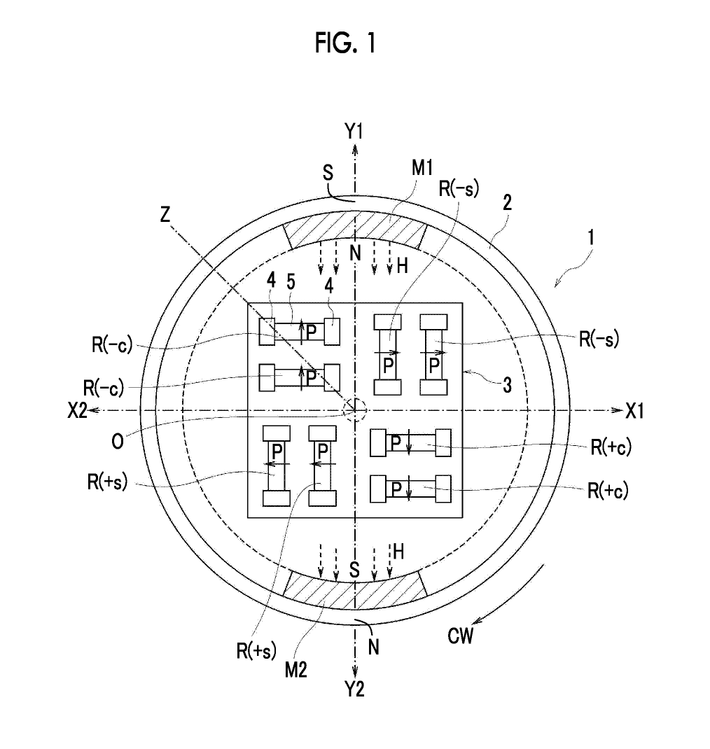

As shown in FIG. 1, an angle detection device 1 according to an embodiment of the disclosure may have a rotational body 2, and a detection substrate 3 which may be disposed on an inner side of the rotational body 2.

In the rotational body 2, two magnets M1 and M2 may be mounted at intervals of 180 degrees. An N pole of the magnet M1 may be directed to the magnet M2, an S pole of the magnet M2 may be directed to the magnet M1, and a magnetic field H may be formed from the magnet M1 toward the magnet M2.

The rotational body 2 may have a rotational center O and rotates clockwise (CW). As a result, on an inner side of the rotational body 2, a rotational magnetic field in which the magnetic field H rotates clockwise may be formed.

On the detection substrate 3, first magnetoresistive effect elements R(+s) and R(−s) and second magnetoresistive effect elements R(+c) and R(−c) may be mounted as magnetic detection elements. In FIG. 1, the detection substrate 3 and the magnetoresistive effect elements may be shown to be large, but the detection substrate 3 and the magnetoresistive effect elements actually may be much smaller in dimension than a diameter of a rotating locus of the magnets M1 and M2. When the rotational body 2 rotates, the rotational magnetic field in the same direction may be applied to each of the magnetoresistive effect elements on the detection substrate 3.

In addition, despite a configuration in which the magnets M1 and M2 are fixed in a fixing unit and the detection substrate 3 may be rotated counterclockwise about the rotational center O, it may be possible to provide the rotational magnetic field which rotates clockwise (CW) relative to the detection substrate 3.

In the first magnetoresistive effect elements R(+s) and R(−s) and the second magnetoresistive effect elements R(+c) and R(−c), directions of sensitivity axes P are orthogonal to each other. Two kinds of the first magnetoresistive effect elements may be provided. Here, the direction of the sensitivity axis P of R(+s) may be an X2 direction, and the direction of the sensitivity axis P of R(−s) may be an X1 direction. Two kinds of the second magnetoresistive effect elements may be provided. Here, the direction of the sensitivity axis P of R(+c) may be a Y2 direction, and the direction of the sensitivity axis P of R(−c) may be a Y1 direction.

The magnetoresistive effect element may be a GMR element using a giant magnetoresistive effect, a TMR element using a tunnel effect, or an AMR element.

As shown in FIG. 1, the magnetoresistive effect element may include electrode portions 4 and 4 and an element portion positioned between the electrode portions 4. The element portion 5 may be formed in a meander pattern within the plane of an X-Y plane, and may be configured by laminating a fixed magnetic layer/a non-magnetic layer/a free magnetic layer. The fixed magnetization direction of the fixed magnetic layer may coincide with the direction of the sensitivity axis P. In the free magnetic layer, a magnetization direction can be changed in accordance with a direction of an external magnetic field H.

When the external magnetic field H is applied in the direction of the sensitivity axis P, an electric resistance value of the magnetoresistive effect element may be a minimum value, and when the external magnetic field H is applied in a reverse direction with respect to the sensitivity axis P, the electric resistance value thereof may be a maximum value. When the external magnetic field H is applied in a direction orthogonal to the sensitivity axis P, the electric resistance value of the magnetoresistive effect element may be a value of the midpoint of the minimum value and the maximum value.

The fixed magnetic layer may be superimposed on an anti-ferromagnetic layer to be subjected to heat treatment in the magnetic field, so that the magnetization direction may be fixed. Also, the fixed magnetic layer may have a lamination ferry structure of the magnetic layer/the non-magnetic intermediate layer/the magnetic layer, and the respective magnetic layers may have a self pinning type which may be magnetized and fixed in anti-parallel. In this case, the magnetization may be fixed by forming one magnetic layer in the magnetic field.

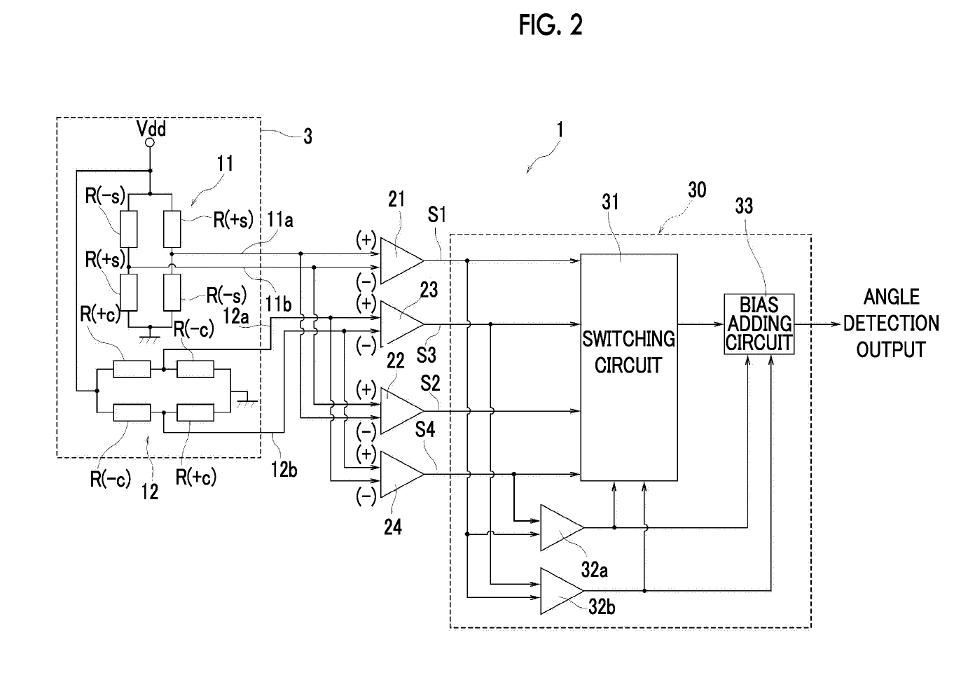

As shown in FIG. 2, in the angle detection device 1, a first magnetic detection unit 11 and a second magnetic detection unit 12 may be configured on the detection substrate 3.

The first magnetic detection unit 11 may be a full bridge circuit constituted of the first magnetoresistive effect elements R(+s) and R(−s) with the directions of the sensitivity axes P different from each other by 180 degrees. The second magnetic detection unit 12 may be a full bridge circuit constituted of the second magnetoresistive effect elements R(+c) and R(−c) with the directions of the sensitivity axes P different from each other by 180 degrees.

As shown in FIG. 2, midpoint outputs (midpoint output voltages) 11a and 11b of the full bridge circuit of the first magnetic detection unit 11 may be applied to a first output circuit 21 and a second output circuit 22. The first output circuit 21 may be a differential amplifier, and the midpoint output 11a may be connected to a (+) input unit and the midpoint output 11b may be connected to a (−) input unit. The second output circuit 22 also may be a differential amplifier, and the midpoint output 11b may be connected to the (+) input unit and the midpoint output 11a may be connected to the (−) input unit.

Midpoint outputs (midpoint output voltages) 12a and 12b of the full bridge circuit of the second magnetic detection unit 12 may be applied to a third output circuit 23 and a fourth output circuit 24. The third output circuit 23 may be a differential amplifier, and the midpoint output 12a is connected to the (+) input unit and the midpoint output 12b is connected to the (−) input unit. The fourth output circuit 24 is also a differential amplifier, and the midpoint output 12b is connected to the (+) input unit and the midpoint output 12a is connected to the (−) input unit.

When the rotational body 2 shown in FIG. 1 rotates clockwise (CW), a first detection output S1 may be obtained from the first output circuit 21, and a second detection output S2 may be obtained from the second output circuit 22. A third detection output S3 may be obtained from the third output circuit 23, and a fourth detection output S4 may be obtained from the fourth output circuit 24.

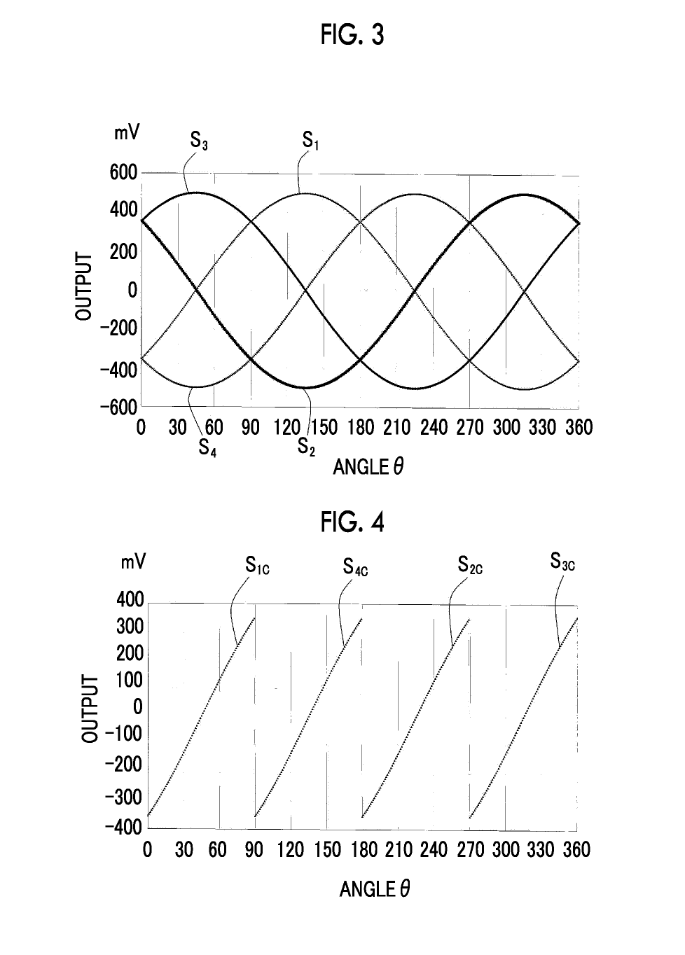

In FIG. 3, output waveforms of the first to fourth detection outputs S1 through S4 are shown. The horizontal axis indicates rotation angle (θ), and the vertical axis indicates output intensity (voltage).

In the first detection output S1 and the second detection output S2, the polarities (positive and negative voltage) may be reversed, and also in the third detection output S3 and the fourth detection output S4, the polarities may be reversed. In the first detection output S1 and the third detection output S3, the phases may be different from each other by 90 degrees, and in the second detection output S2 and the fourth detection output S4, the phases also may be different from each other by 90 degrees. One of the first detection output S1 and the third detection output S3 may be an output having a change approximating a trigonometric function wave of a sine wave, and the other thereof may be an output having a change approximating a trigonometric wave of a cosine wave.

The rotation angle θ of the rotational body 2 is shown in the horizontal axis of FIG. 3, but the representation of the rotation angle θ uses a case in which a width center of the magnet M1 shown in FIG. 1 coincides with each other on a reference line Z, as the origin (0 degrees). FIG. 1 shows a state in which the magnet M1 of the rotational body 3 in rotation advances by 45 degrees clockwise (CW) with the origin (reference axis Z) as a starting point. In this instance, output intensities of the first to fourth detection outputs S1 to S4 become an output intensity when the horizontal axis in FIG. 3 is 45 degrees. When the horizontal axis is 45 degrees, the output intensity of the first detection output S1 and the output intensity of the second detection output S2 are values of midpoints, the output intensity of the third detection output S3 is a maximum value, and the output intensity of the fourth detection output S4 is a minimum value.

Absolute values and amplitudes of intensities of output waveforms of the first to fourth detection outputs S1 through S4 shown in FIG. 3 depend on a gain or the like which is set to a power supply voltage Vdd and depend on the output circuits 21, 22, 23, and 24 each being a differential amplifier. The first to fourth detection outputs S1 to S4 are analog outputs in which changes in the detection outputs from the first and second magnetic detection units 11 and 12 which detect a rotational magnetic field are reflected as is.

As shown in FIG. 2, the first to fourth detection outputs S1 through S4 may be applied to an analog mixer 30. The analog mixer 30 may have a switching circuit 31, comparators 32a and 32b, and a bias adding circuit 33.

The first comparator 32a may compare the level of the intensities of the first detection output S1 and the fourth detection output S4, and the comparison result may be applied to the switching circuit 31. The second comparator 32b may compare the level of the intensities of the first detection output S1 and the third detection output S3, and the comparison result may be applied to the switching circuit 31.

The switching circuit 31 may perform a switching operation based on the comparison results of the comparators 32a and 32b so that the detection output is cut out as a partial detection output in which any one of the first to fourth detection outputs S1 to S4 is selected.

Based on the comparison result of the first comparator 32a, the comparison result of the second comparator 32b, and the comparison result therebetween, the detection output which is cut out in the switching circuit 31 is as described in Table 1 below.

TABLE 1

| First | Second | Switching output | |
|---|---|---|---|
| comparator 32a | comparator 32b | (partial detection output) | Bias voltage |
| S1 > S4 | S1 < S3 | S1 (S1c) | +350 mV |
| S1 > S4 | S1 > S3 | S4 (S4c) | +1050 mV |
| S1 < S4 | S1 > S3 | S2 (S2c) | +1750 mV |
| S1 < S4 | S1 < S3 | S3 (S3c) | +2450 mV |

In FIG. 4, partial detection outputs S1c, S4c, S2c, and S3c which are cut out by the switching operation of the switching circuit 31 are shown.

As shown in Table 1, switching may be performed in the switching circuit 31 by comparing two detection outputs in each of the first comparator 32a and the second comparator 32b, and therefore four detection outputs are cut out at intervals of 90 degrees while the rotational body 2 rotates 360 degrees clockwise as shown in FIG. 4.

When the angle θ is between approximately 0 and 90 degrees, as shown in the first column of Table 1, the first detection output S1 is cut out back and forth relative to a midpoint of its amplitude (voltage width) in a range of 45 degrees, thereby obtaining a partial detection output S1c shown in FIG. 4. When the angle θ is between approximately 90 and 180 degrees, as shown in the second column of Table 1, the fourth detection output S4 is cut out back and forth relative to a midpoint of its amplitude (voltage width) in a range of 45 degrees, thereby obtaining a partial detection output S4c shown in FIG. 4. In the same manner, a partial detection output S2c may be obtained when the angle of θ is between approximately 180 and 270 degrees, and a partial detection output S3c may be obtained when the angle of θ is between approximately 270 and 360 degrees.

Since the partial detection outputs S1c, S4c, S2c, and S3c are cut out back and forth relative to the midpoint of the amplitude in the range of ±45 degrees among the detection outputs approximating the sine wave and the cosine wave, a change in output intensity may become nearly a linear function.

The first comparator 32a and the second comparator 32b may generate a signal for dividing the detection output for each interval of 90 degrees in which the partial detection output shown in FIG. 4 can be obtained. To the extent that this is possible, compared detection outputs are not limited to the example shown in Table 1.

For example, even in a comparison condition of S3>S1 and S3>S2, the first detection output S1 can be cut out when the angle of θ is in a range of approximately 0 to 90 degrees, thereby obtaining the partial detection output S1c.

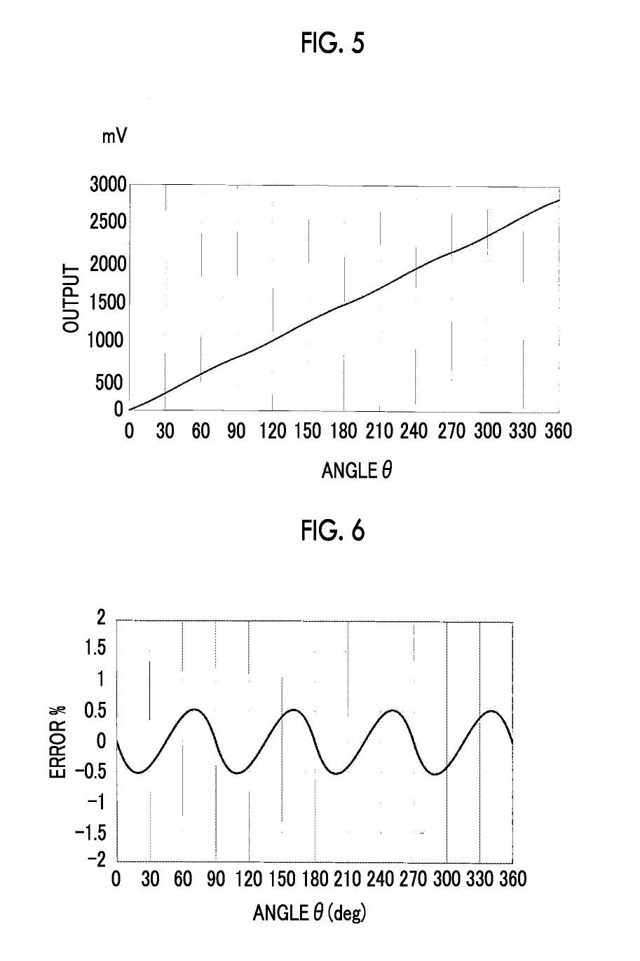

The partial detection outputs S1c, S4c, S2c, and S3c which may be cut out in the switching circuit 31 are applied to the bias adding circuit 33. In the bias adding circuit 33, a positive or negative bias voltage is applied to the partial detection outputs S1c, S4c, S2c, and S3c, whereby an angle detection output approximating the linear function in which the partial detection outputs S1c, S4c, S2c, and S3c are consecutive can be obtained as shown in FIG. 5. In the rightmost column of Table 1, in order to obtain the angle detection output shown in FIG. 5, the bias voltages applied to the partial detection outputs S1c, S4c, S2c, and S3c are shown numerically.

The bias adding circuit may be constituted of a resistor, a variable resistor, and the like, and the bias voltage is applied to the partial detection output S4c so that a starting end of the partial detection output S4c shown in FIG. 4 is connected to a terminating end of the partial detection output S1c. Similarly, the bias voltage may be applied to the partial detection outputs S2c and S3c. In addition, by applying the positive or negative bias voltage to the partial detection output S1c which can be first obtained, a starting point of the output when the angle θ is approximately 0 degrees can be aligned with the origin of the output voltage as shown in FIG. 5.

The change in the angle detection output shown in FIG. 5 is approximating a linear function. FIG. 6 shows an intensity error between the angle detection output shown in FIG. 5 and the linear function. An error for the linear function of the angle detection output is approximately ±0.5%.

In the angle detection device 1 according to an embodiment of the present invention, an analog output which can be obtained from the first magnetic detection unit 11 and the second magnetic detection unit 12 is used as is or used by performing gain adjustment, whereby the angle detection output approximating the linear function can be instantaneously obtained. Thus, even when the rotational body 2 rotates to be directly connected to a motor, it is possible to accurately detect a rotation angle.

In addition, in the angle detection device 1 shown in FIGS. 1 and 2, the first magnetic detection unit 11 is a full bridge circuit constituted of the first magnetoresistive effect elements R(+s) and R(−s), and the second magnetic detection unit 12 is a full bridge circuit constituted of the second magnetoresistive effect elements R(+c) and R(−c).

However, in the present disclosure, the first magnetic detection unit 11 may be a half-bridge circuit using any one of R(+s) and R(−s) as the first magnetoresistive effect element, and the second magnetic detection unit 12 may be a half-bridge circuit using any one of R(+c) and R(−c) as the second magnetoresistive effect element.

In addition, in the analog mixer 30 shown in FIG. 2, the bias power is applied to each of the partial detection outputs cut out in the switching circuit 31, but the bias power is applied in advance to the first to fourth detection outputs S1 to S4 having passed through the first to fourth output circuits 21, 22, 23, and 24, and therefore consecutive angle detection outputs may be obtained from the switching circuit 31 by cutting out the partial detection output in the switching circuit 31.

It should be understood by those skilled in the art that various modifications, combinations, sub-combinations and alterations may occur depending on design requirements and other factors insofar as they are within the scope of the appended claims of the equivalents thereof.

Accordingly, the embodiments of the present inventions are not to be limited in scope by the specific embodiments described herein. Further, although some of the embodiments of the present disclosure have been described herein in the context of a particular implementation in a particular environment for a particular purpose, those of ordinary skill in the art should recognize that its usefulness is not limited thereto and that the embodiments of the present inventions can be beneficially implemented in any number of environments for any number of purposes. Accordingly, the claims set forth below should be construed in view of the full breadth and spirit of the embodiments of the present inventions as disclosed herein. While the foregoing description includes many details and specificities, it is to be understood that these have been included for purposes of explanation only, and are not to be interpreted as limitations of the invention. Many modifications to the embodiments described above can be made without departing from the spirit and scope of the invention.

What is claimed is:

1. An angle detection device comprising:
a first magnetic detection unit configured to be provided in a detection area to which a rotational magnetic field is applied so as to obtain a detection output approximating a sine wave being a function of a rotation angle of the rotational magnetic field;
a second magnetic detection unit configured to be provided in the detection area to which the rotational magnetic field is applied so as to obtain a detection output approximating a cosine wave being a function of the rotation angle of the rotational magnetic field;
a switching circuit configured to cut out a plurality of partial detection outputs approximating a linear function from analog detection outputs obtained from the first and second magnetic detection units; and
a bias adding circuit configured to enable the plurality of partial detection outputs to be consecutive by applying a bias power to any one of the partial detection outputs so that the consecutive partial detection outputs are used as angle detection outputs.

2. The angle detection device according to claim 1, further comprising:
an output circuit configured to obtain a first detection output from the first magnetic detection unit and a second detection output obtained by reversing positive/negative polarity with the first detection output, and a third detection output from the second magnetic detection unit and a fourth detection output obtained by reversing positive/negative polarity with the third detection output; and
a comparator configured to compare either the first and second detection outputs or the third and fourth detection outputs,
wherein switching timing of the switching circuit is determined based on a comparison output from the comparator.

3. The angle detection device according to claim 2, wherein each of the first, second, third, and fourth detection outputs is cut out at intervals of 90 degrees by the switching circuit so that the partial detection outputs are obtained.

4. The angle detection device according to claim 3, wherein the first, second, third, and fourth detection outputs are cut out in a range of ±45 degrees with a midpoint of the amplitude as a starting point.

5. The angle detection device according to claim 1, wherein each of the first and second magnetic detection units is constituted of a bridge circuit including a magnetoresistive effect element, and in a first magnetoresistive effect element included in the first magnetic detection unit and a second magnetoresistive effect element included in the second magnetic detection unit, directions of sensitivity axes are orthogonal to each other.
